(19) United States
(12) Patent Application Publication
(10) Pub. No.: US 2016/0163363 A1
(43) Pub. Date: Jun. 9, 2016

(54) SEMICONDUCTOR MEMORY APPARATUS AND INPUT BUFFER THEREFOR

(71) Applicant: SK hynix Inc., Icheon-si Gyeonggi-do (KR)

(72) Inventor: Jin Ha HWANG, Icheon-si Gyeonggi-do (KR)

(21) Appl. No.: 14/625,878

(22) Filed: Feb. 19, 2015

(30) Foreign Application Priority Data
Dec. 5, 2014 (KR) 10-2014-0174438

(51) Int. Cl. G11C 7/10

(52) U.S. Cl. CPC G11C 7/1084

(57) ABSTRACT

A semiconductor memory apparatus may include an input buffer configured to receive an external signal, boost the external signal to a frequency according to an operation mode signal, and generate an internal signal; and an internal circuit configured to operate by receiving the internal signal.

### CROSS-REFERENCES TO RELATED APPLICATION

This application claims priority under 35 U.S.C. §119(a) to Korean application No. 10-2014-0174438, filed on Dec. 5, 2014, in the Korean Intellectual Property Office, which is incorporated by reference in its entirety as set forth in full.

### BACKGROUND

1. Technical Field

Various embodiments relate to a semiconductor integrated apparatus, and more particularly, to a semiconductor memory apparatus and an input buffer therefor.

2. Related Art

A semiconductor memory apparatus includes an input buffer that receives and amplifies an external small signal and provides an internal circuit with an amplified signal.

The input buffer should exactly buffer an inputted external signal and is requested to use a small amount of current.

The semiconductor memory apparatus are fabricated to support various operation modes which may changed according to an applied host apparatus. The operation modes, for example, may include an operation frequency.

Accordingly, a signal outputted from the input buffer should be matched with an operation speed of the semiconductor memory apparatus.

### SUMMARY

In an embodiment, a semiconductor memory apparatus may include an input buffer configured to receive an external signal, boost the external signal to a frequency according to an operation mode signal, and generate an internal signal. The semiconductor memory apparatus may also include an internal circuit configured to operate by receiving the internal signal.

In an embodiment, the input buffer may include an amplification unit configured to amplify the external signal and generate an amplified signal. The input buffer may also include a driving unit configured to boost the amplified signal to the frequency determined according to the operation mode signal, and generate the internal signal.

In an embodiment, a semiconductor apparatus may include an input buffer configured to boost an amplified signal and output an internal signal according to an operation mode signal that indicates an operation speed of the semiconductor memory apparatus. The semiconductor apparatus may also include an internal circuit configured to receive the internal signal from the input buffer.

### BRIEF DESCRIPTION OF THE DRAWINGS

FIG. 1 is a configuration diagram of a semiconductor memory apparatus according to an embodiment;

FIG. 2 is a configuration diagram of an input buffer according to an embodiment;

FIG. 3 is a configuration diagram of a driving unit according to an embodiment;

FIG. 4 is a circuit diagram of a driving unit according to an embodiment;

FIG. 5 and FIG. 6 are diagrams of a boosting section;

FIG. 7 is a configuration diagram of an amplification unit according to an embodiment; and

FIG. 8 is a configuration diagram of an electronic system according to an embodiment.

### DETAILED DESCRIPTION

Various embodiments will be described in greater detail with reference to the accompanying figures. The various embodiments are described with reference to cross-sectional illustrations that are schematic illustrations of embodiments (including intermediate structures). As such, variations from the illustrations in shape due to differences in, for example, manufacturing techniques and/or tolerances are to be expected. Thus, embodiments should not be construed as limited to the particular shapes illustrated but may include modifications. In the figures, lengths and sizes of layers and regions may be exaggerated for clarity. Like reference numerals in the figures denote like elements. It is also understood that when a layer is referred to as being “on” another layer or substrate, it can be directly on the other layer or substrate, or intervening layers may also be present. It is also noted that in this specification, “connected/coupled” refers to where one component is connected/coupled to another component either directly or indirectly, through an intermediate component. In addition, a singular form may include a plural form, and vice versa, as long as it is not specifically mentioned otherwise.

Embodiments are described with reference to cross-section and/or plan illustrations that are schematic illustrations. However, embodiments should not be construed as limited thereto. Although a few embodiments will be shown and described, it will be appreciated that changes may be made in these embodiments.

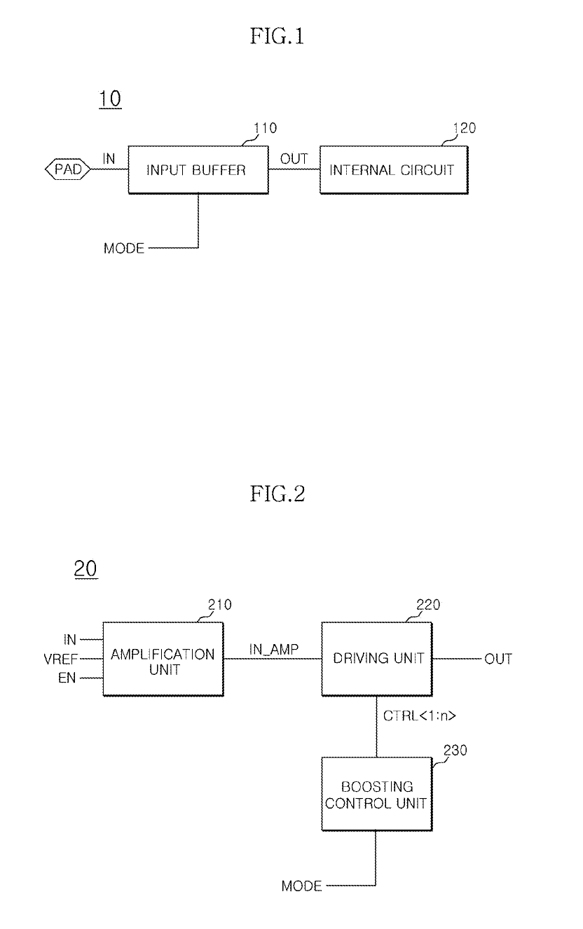

Referring to FIG. 1, a configuration diagram of a semiconductor memory apparatus according to an embodiment is illustrated.

A semiconductor memory apparatus 10 illustrated in FIG. 1 may include an input buffer 110 and an internal circuit 120.

The input buffer 110 may receive an external signal IN through a pad PAD and also amplify the external signal IN. The input buffer 110 may boost an amplified signal and output an internal signal OUT according to an operation mode signal MODE of the semiconductor memory apparatus 10.

The internal circuit 120 may operate in response to the internal signal OUT provided from the input buffer 110.

In an embodiment, the operation mode signal MODE may indicate information representing an operation speed of the semiconductor memory apparatus 10. Accordingly, the input buffer 110 may boost the external signal IN to a frequency that matches with the operation speed of the semiconductor memory apparatus 10. Further, the input buffer 110 may output the internal signal OUT.

Accordingly, the input buffer 110 may change and output a frequency for boosting an external signal according to the operation speed of the semiconductor memory apparatus 10. For example, the operation speed of the semiconductor memory apparatus 10 and a frequency of a signal outputted from the input buffer 110 may be proportional. The input buffer 110 may be controlled such that the operation speed of the semiconductor memory apparatus 10 and a frequency of the internal signal are proportional to each other.

Referring to FIG. 2, a configuration diagram of an input buffer according to an embodiment is illustrated.

An input buffer 20 according to an embodiment may include an amplification unit 210, a driving unit 220, and a boosting control unit 230.

The amplification unit 210 may be driven according to an enable signal EN to amplify the external signal IN in response to a comparison result of the external signal IN and a reference signal VREF. The amplification unit 210 may also output an amplified signal IN_AMP.

The driving unit 220 may receive the amplified signal IN_AMP, boost the amplified signal IN_AMP to a frequency decided according to a control signal CTRL<1:n>, and generate an internal signal OUT. The control signal CTRL<1:n>, for example, may include a multi-bit digital code. Accordingly, the driving unit 220 can boost the amplified signal IN_AMP to the frequency decided on the operation mode signal MODE and generate the internal signal OUT.

The boosting control unit 230 may receive the operation mode signal MODE and output the control signal CTRL<1:n>.

In an embodiment, the boosting control unit 230 may use a CAS (Column Address Strobe) write latency (programmable CAS Write Latency; CWL) signal as the operation mode signal MODE. The CWL signal may have a value previously stored in a mode register set (MRS) in correspondence to an operation speed of a semiconductor memory apparatus.

In an embodiment, the boosting control unit 230, for example, may decode the operation mode signal MODE based on the CWL signal. In addition, the boosting control unit 230 may generate the control signal CTRL<1:n>.

The amount of a current flowing between an input terminal and an output terminal of the driving unit 220 may be decided according to a logic level of the control signal CTRL<1:n> generated in the boosting control unit 230 so that a boosting frequency of the internal signal OUT generated in the driving unit 220 is decided as a result.

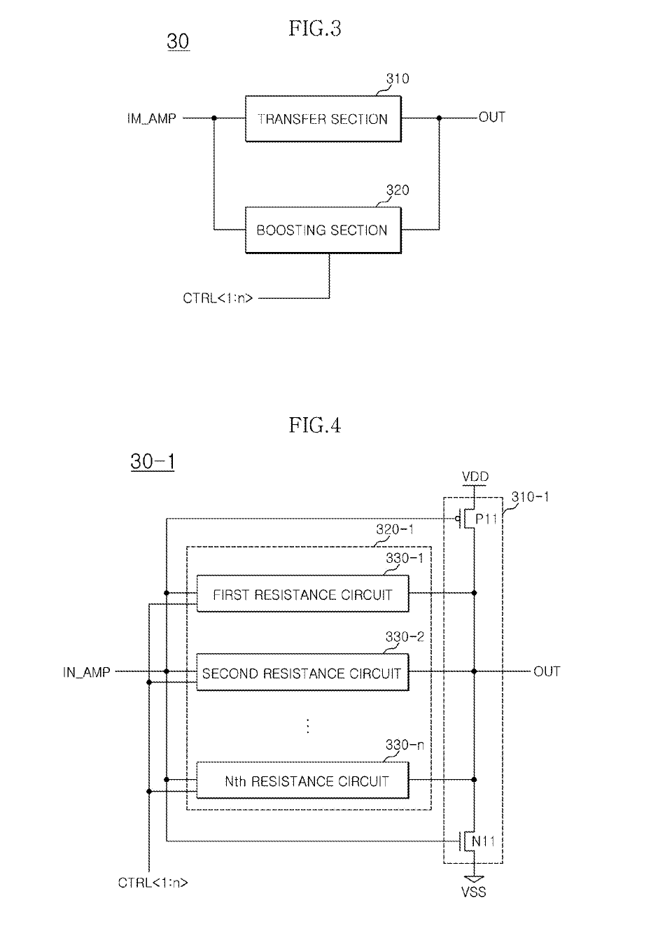

Referring to FIG. 3, a configuration diagram of a driving unit according to an embodiment, wherein the driving unit may include a transfer section 310 and a boosting section 320 is illustrated.

The transfer section 310 may drive the amplified signal IN_AMP and generate the internal signal OUT. The transfer section 310, for example, may include an inverter, but is not limited thereto.

The boosting section 320 may be electrically coupled between an amplified signal (IN_AMP) input terminal and an internal signal (OUT) output terminal. The boosting section 320 may be configured to boost the amplified signal IN_AMP to a frequency determined according to the control signal CTRL<1:n> based on the operation mode signal MODE. The boosting section 320 may decide the amount of a current of the amplified signal IN_AMP flowing between an input terminal and an output terminal of the driving unit 30 according to the control signal CTRL<1:n>. The boosting section 320, for example, may include a plurality of resistance circuits electrically coupled between the input terminal and the output terminal of the driving unit 30 in parallel. Further, a resistance value of each of the plurality of resistance circuits may be decided according to the control signal CTRL<1:n>.

Referring to FIG. 4, a circuit diagram of a driving unit according to an embodiment is illustrated.

A transfer section 310-1 provided in a driving unit 30-1 illustrated in FIG. 4 may include an inverter electrically coupled between a power supply voltage terminal VDD and a ground terminal VSS. The inverter, for example, may include a transistor P11 electrically coupled between the power supply voltage terminal VDD and the internal signal (OUT) output terminal. The inverter may also include a transistor N11 electrically coupled between the internal signal (OUT) output terminal and the ground terminal VSS.

A boosting section 320-1 may include a plurality of resistance circuits 330-1 to 330-n electrically coupled between the amplified signal (IN_AMP) input terminal and the internal signal (OUT) output terminal in parallel and controlled by the control signal CTRL<1:n>.

Each of the resistance circuits 330-1 to 330-n, for example, may include a switching element driven in response to the control signal CTRL<1:n>.

Referring to FIG. 5, is a diagram of a boosting section 320-2 is illustrated.

Each of the resistance circuits 331-1 to 331-n included in the boosting section 320-2 illustrated in FIG. 5 may include switching elements SW11 to SW1n driven in response to the control signal CTRL<1:n>.

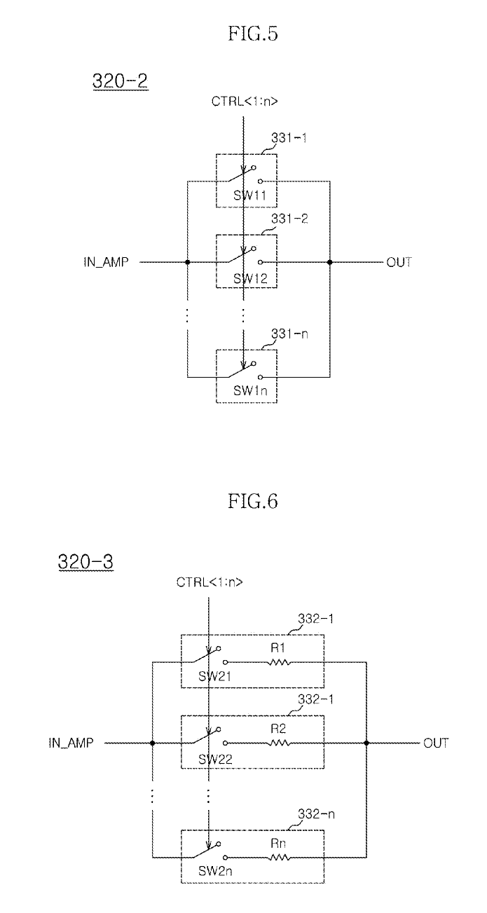

Referring to FIG. 6, a diagram of a boosting section 320-3 is illustrated.

Each of the resistance circuits 332-1 to 332-n included in the boosting section 320-3 illustrated in FIG. 6 may include switching elements SW21 to SW2n. The switching elements SW21 to SW2n are driven in response to the control signal CTRL<1:n> and resistive elements R1 to Rn serially electrically coupled to the switching elements SW21 to SW2n.

Since the boosting sections 320-2 and 320-3 illustrated in FIG. 5 and FIG. 6 are for illustrative purposes only, it is possible to employ all configurations including resistance circuits having resistance values decided according to the control signal CTRL<1:n>.

In an embodiment, it is possible to control the resistance values of the resistance circuits constituting the boosting sections 320, 320-1, 320-2, and 320-3 to be reduced as an operation speed of a semiconductor memory apparatus becomes fast. More specifically, it is possible to control the operation speed of the semiconductor memory apparatus to be inversely proportional to the resistance values of the boosting sections 320, 320-1, 320-2, and 320-3. Accordingly, as the operation speed of the semiconductor memory apparatus is high, the frequencies of signals outputted from the driving units 220, 30, and 30-1, or, the frequencies of the internal signals OUT outputted from the input buffers 110 and 20 may also be controlled to be high.

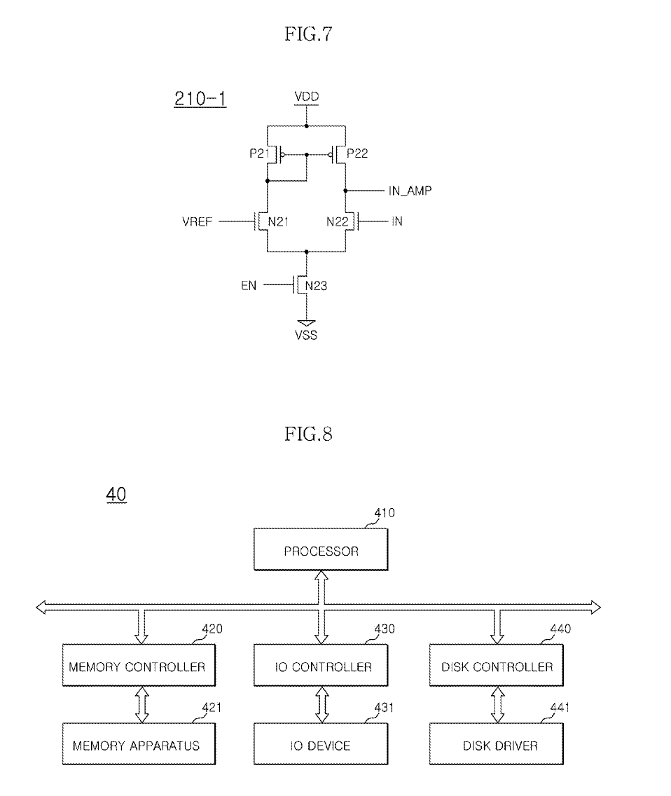

Referring to FIG. 7, a configuration diagram of an amplification unit according to an embodiment is illustrated.

In an embodiment, an amplification unit 210-1 may include a differential amplification circuit, and an example thereof is illustrated in FIG. 7 below.

The amplification unit 210-1 may include a bias switching element N23 and first to fourth switching elements P21, P22, N21, and N22.

The bias switching element N23 may be driven in response to the enable signal EN. The bias switching element N23 may be electrically coupled to the ground terminal VSS. The first and second switching elements P21 and P22 may be electrically coupled to the power supply voltage terminal VDD and gate terminals thereof may be electrically coupled to each other, thereby configuring a current mirror. The third switching element N21 may be electrically coupled between the first switching element P21 and the bias switching element N23 and may be driven according to the reference signal VREF. In addition, the fourth switching element N22 may be electrically coupled between the second switching element P22 and the bias switching element N23 and may be driven according to the external signal IN.

As the enable signal EN is enabled, the amplification unit 210-1 starts to operate.

When the external signal IN having a level higher than that of the reference signal VREF is inputted, the amplified signal IN_AMP may be outputted at a logic low level as a result.

In this case, the aforementioned driving units 220 and 30 invert the amplified signal IN_AMP at the logic low level to a logic high level. In addition the driving units 220 and 30 boost the amplified signal IN_AMP to a frequency decided according to the logic level of the control signal CTRL<1:n>, and output the internal signal OUT.

When the external signal IN having a voltage level lower than that of the reference signal VREF is applied, the amplified signal IN_AMP has a logic high level.

In this instance, the driving units 220 and 30 invert the amplified signal IN_AMP at the logic high level to a logic low level. Further, the driving units 220 and 30 boost the amplified signal IN_AMP to the frequency decided according to the logic level of the control signal CTRL<1:n>, and output the internal signal OUT.

Referring to FIG. 8, a configuration diagram of an electronic system according to an embodiment is illustrated.

An electronic system 40 according to an embodiment may include a processor 410, a memory controller 420, a memory apparatus 421, an IO controller 430, an IO device 431, a disk controller 440, and a disk driver 441.

One or more processors 410 may be provided. The one or more processors 410 may operate independently or in cooperation with another processor. The processor 410 has an environment capable of communicating with other elements. The other elements may include for example, the memory controller 420, the IO controller 430, and the disk controller 440, through a bus (a control bus, an address bus, or a data bus).

The memory controller 420 is electrically coupled to one or more memory apparatuses 421. The memory controller 420 receives a request provided from the processor 410. The memory controller 420 also controls the one or more memory apparatuses 421 based on the request.

The memory apparatus 421, for example, may include the aforementioned semiconductor memory apparatus.

The IO controller 430 may be electrically coupled between the processor 410 and the IO device 431. The IO controller 430 may transfer input from the IO device 431 to the processor 410 or provide a processing result of the processor 410 to the IO device 431. The IO device 431 may include an input device such as a keyboard, a mouse, a touchscreen, or a microphone. The IO device 431 may also include an output device such as a display or a speaker.

The disk controller 440 may control one or more disk drivers 441 under the control of the processor 410.

In such an electronic system 40, when an external signal is inputted to the memory apparatus 421 under the control of the processor 410, the input buffers 110 and 20 provided in the semiconductor memory apparatus 421 may be configured to amplify the external signal. The input buffers 110 and 20 may also boost the external signal amplified to a frequency based on the operation speed of the semiconductor memory apparatus 421, generate the internal signal OUT, and provide the internal signal OUT to an internal circuit.

The configuration examples of the input buffers 110 and 20 may employ the configurations illustrated in FIG. 2 to FIG. 7, but are not limited thereto to the descriptions above.

The above embodiments of the invention are illustrative and not limitative. Various alternatives and modifications are possible in addition to what is described above.

What is claimed is:

1. A semiconductor memory apparatus comprising:
an input buffer configured to receive an external signal, boost the external signal to a frequency according to an operation mode signal, and generate an internal signal; and
an internal circuit configured to operate by receiving the internal signal.

2. The semiconductor memory apparatus according to claim 1, wherein the operation mode signal is indicates information that represents an operation speed of the semiconductor memory apparatus.

3. The semiconductor memory apparatus according to claim 1, wherein the input buffer is controlled such that an operation speed of the semiconductor memory apparatus and a frequency of the internal signal are proportional.

4. The semiconductor memory apparatus according to claim 1, wherein the input buffer comprises:
an amplification unit configured to amplify the external signal and generate an amplified signal; and
a driving unit configured to boost the amplified signal to the frequency determined according to a control signal, and generate the internal signal.

5. The semiconductor memory apparatus according to claim 1, wherein the input buffer further comprises:
a boosting control unit to generate a control signal according to the operation mode signal.

6. The semiconductor memory apparatus according to claim 4, wherein the driving unit comprises:
a transfer section configured to drive the amplified signal and generate the internal signal; and
a boosting section configured to be electrically coupled between an input terminal of the amplified signal and an output terminal of the internal signal, and to boost the amplified signal to a frequency decided according to the control signal based on the operation mode signal.

7. The semiconductor memory apparatus according to claim 6, wherein the boosting section comprises:
a plurality of resistance circuits electrically coupled between the input terminal of the amplified signal and the output terminal of the internal signal in parallel, wherein resistance values of the plurality of resistance circuits are decided by the control signal.

8. The semiconductor memory apparatus according to claim 7, wherein each of the plurality of resistance circuits comprises:
a switching element driven by the control signal.

9. An input buffer comprising:
an amplification unit configured to amplify an external signal and generate an amplified signal; and
a driving unit configured to boost the amplified signal to a frequency determined according to an operation mode signal, and generate an internal signal.

10. The input buffer according to claim 9, wherein the operation mode signal is determined according to an operation speed of a semiconductor memory apparatus.

11. The input buffer according to claim 9, wherein a frequency of the internal signal is controlled to be proportional to an operation speed of a semiconductor memory apparatus.

12. The input buffer according to claim 9, further comprising:
a boosting control unit configured to generate a control signal according to the operation mode signal.

13. The input buffer according to claim 9, wherein the driving unit comprises:
a transfer section configured to drive the amplified signal and generate the internal signal; and
a boosting section configured to be electrically coupled between an input terminal of the amplified signal and an output terminal of the internal signal, and to boost the amplified signal to a frequency determined according to a control signal based on the operation mode signal.

14. The input buffer according to claim 13, wherein the boosting section comprises:
a plurality of resistance circuits electrically coupled between the input terminal of the amplified signal and the output terminal of the internal signal in parallel, wherein resistance values of the plurality of resistance circuits are determined according to the control signal.

15. The input buffer according to claim 14, wherein each of the plurality of resistance circuits comprises:
a switching element driven by the control signal.

16. A semiconductor memory apparatus comprising:
an input buffer configured to boost an amplified signal and output an internal signal according to an operation mode signal that indicates an operation speed of the semiconductor memory apparatus; and
an internal circuit configured to receive the internal signal from the input buffer.

17. The semiconductor memory apparatus according to claim 16, wherein the input buffer configured to boost an external signal to a frequency matching the operation speed of the semiconductor memory apparatus.

18. The semiconductor memory apparatus according to claim 16, wherein the input buffer generates the internal signal in response to the operation mode signal and an external signal.

19. The semiconductor memory apparatus according to claim 17, wherein the input buffer outputs the internal signal when the external signal is boosted to the frequency that matches the operation speed of the semiconductor memory apparatus.

20. The semiconductor memory apparatus according to claim 16, wherein the operation mode signal is proportional to a frequency of a signal outputted from the input buffer.
